(19) United States
(12) Patent Application Publication
(10) Pub. No.: US 2024/0312689 A1
(43) Pub. Date: Sep. 19, 2024

(54) UTILIZATION OF INDUCTORS IN ELECTRONICS CIRCUITS AS MAGNETOHYDRODYNAMICS PUMPS FOR LIQUID METAL BASED COOLING

(71) Applicant: Ohio State Innovation Foundation, Columbus, OH (US)

(72) Inventors: Jin Wang, Powell, OH (US); Junchong Fan, Dublin, OH (US)

(21) Appl. No.: 18/273,319

(22) PCT Filed: Nov. 24, 2021
(86) PCT No.: PCT/US2021/060753

§ 371 Date: Jul. 20, 2023

Related U.S. Application Data
(60) Provisional application No. 63/141,040, filed on Jan. 25, 2021.

(51) Int. Cl. H01F 27/10; H01F 27/24

(52) U.S. Cl. CPC H01F 27/10; H01F 27/24

(57) ABSTRACT

A liquid metal cooling system configuration is described. A system comprises a magnetohydrodynamics (MHD) pump and an inductor. The MHD pump may be integrated into the inductor. The MHD pump may be comprised within the inductor. The inductor comprising the integrated MHD pump may be configured to connect two blocks of circuits. A liquid metal cooling system comprises an MHD pump, a cooling pad, and a radiator. The inductor may comprise an integrated MHD pump.

### CROSS-REFERENCE TO RELATED APPLICATIONS

This application claims the benefit of U.S. provisional patent application No. 63/141,040, filed on Jan. 25, 2021, and entitled “UTILIZATION OF INDUCTORS IN ELECTRONICS CIRCUITS AS MAGNETOHYDRODYNAMICS PUMPS FOR LIQUID METAL BASED COOLING,” the disclosure of which is expressly incorporated herein by reference in its entirety.

### STATEMENT OF GOVERNMENT SUPPORT

This invention was made with government support under DE-AC05-00OR22725 awarded by the U.S. Department of Energy. The government has certain rights in the invention.

### BACKGROUND

Liquid cooling systems offer benefits over air cooling systems in terms of cooling efficiency and thermal dissipation ability. Areas suitable for liquid cooling systems include electric vehicles, large-scale data centers, high power density converters, new generation power modules, and aerospace applications, for example. The aforementioned applications require high stability and reliability. High-power density designs and packages face severe thermal dissipation issues due to confined space. Liquid cooling in these applications will provide higher thermal performance and guarantee stability. As the capacities of electric vehicles and the information industry escalate, developing new generation semiconductor devices and power modules with innovative liquid cooling strategies are essential to improving the performance of power converters.

A major impediment to liquid cooling systems has been the mechanical pump which reduces the overall reliability of the system. Also, thermal conductivity of a conventional coolant like water is limited, which lowers the heat exchange efficiency between a thermal pad and the coolant.

Existing solutions include: 1) a high thermal conductivity coolant, and 2) a magnetohydrodynamics (MHD) pump system. A high thermal conductivity coolant is still driven by a conventional mechanical pump. To eliminate moving parts, improve overall reliability, and improve cooling performance, an MHD pump together with a liquid metal coolant is seen as a promising solution.

An MHD pump system utilizes Lorentz force to drive a conductive liquid metal coolant, and a permanent magnet or an electromagnet are used to provide the perpendicular magnetic field. As an example, FIG. 1 shows a vector diagram 100 of the Lorentz force inside an MHD pump used in a conventional liquid metal nuclear reactor cooling system and micropump system (e.g., see O. M. Al-Habahbeh, M. Al-Saqqa, M. Safi, T. Abo Khater, Review of magnetohydrodynamic pump applications, Alexandria Engineering Journal, Volume 55, Issue 2, 2016, Pages 1347-1358, ISSN 1110-0168). The Lorentz force is produced when an electric current is applied across a channel filled with a conducting coolant in the presence of a perpendicular magnetic field. A permanent magnet or an electromagnet provides the magnetic field needed in the pump. These magnetic components add complexity and costs to the system, and electromagnetic compatibility issues should also be taken into consideration. Moreover, another auxiliary power supply is essential to provide current flow through the conducting liquid.

It is with respect to these and other considerations that the various aspects and embodiments of the present disclosure are presented.

### SUMMARY

A liquid metal cooling system configuration is described. A system comprises a magnetohydrodynamics (MHD) pump and an inductor. The MHD pump may be integrated into the inductor. The MHD pump may be comprised within the inductor. The inductor comprising the integrated MHD pump may be configured to connect two blocks of circuits. A liquid metal cooling system comprises an MHD pump, a cooling pad, and a radiator. An inductor may comprise the MHD pump.

In an implementation, a system comprises: an inductor with a magnetic core structure and a gap in a core structure; and a magnetohydrodynamics (MHD) pump comprised within the inductor.

In an implementation, a liquid metal cooling system comprises: an inductor comprising an integrated magnetohydrodynamics (MHD) pump; a cooling pad; a radiator; and a liquid metal coolant that carries heat from the cooling pad to the radiator.

In an implementation, a system comprises: an inductor with a core structure that provide a close-loop path for magnetic flux; and an integrated magnetohydrodynamics (MHD) pump, wherein the inductor comprises the integrated MHD pump, wherein the inductor is configured to connect two blocks of circuits.

This summary is provided to introduce a selection of concepts in a simplified form that are further described below in the detailed description. This summary is not intended to identify key features or essential features of the claimed subject matter, nor is it intended to be used to limit the scope of the claimed subject matter.

### BRIEF DESCRIPTION OF THE DRAWINGS

The foregoing summary, as well as the following detailed description of illustrative embodiments, is better understood when read in conjunction with the appended drawings. For the purpose of illustrating the embodiments, there is shown in the drawings example constructions of the embodiments; however, the embodiments are not limited to the specific methods and instrumentalities disclosed. In the drawings:

FIG. 1 is a vector diagram of the Lorentz force inside a magnetohydrodynamics (MHD) pump;

FIG. 2 is a diagram of an implementation of a liquid metal cooling system;

FIG. 3 shows a diagram of an implementation of a system with multiple channels with a C-shape magnetic core;

FIG. 4 shows a diagram of an implementation of a system with a single channel with a C-shape magnetic core;

FIG. 5 shows a diagram of an implementation of a system with multiple channels with a rod magnetic core;

FIG. 6 shows a diagram of an implementation of a system with a single channel with a rod magnetic core;

FIG. 7 shows a diagram of an implementation of a system with multiple channels with an EI magnetic core,

FIG. 8 shows a diagram of an implementation of a system with a single channel with an EI magnetic core;

FIG. 9 shows an implementation of series connection topology; and

FIG. 10 shows an implementation of parallel connection topology.

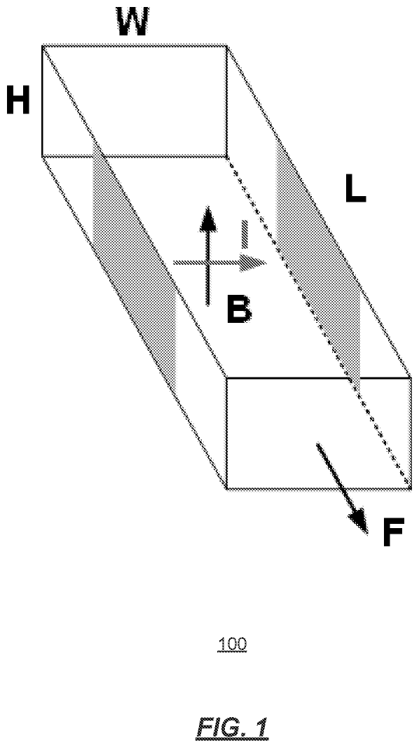

### DETAILED DESCRIPTION

This description provides examples not intended to limit the scope of the appended claims. The figures generally indicate the features of the examples, where it is understood and appreciated that like reference numerals are used to refer to like elements. Reference in the specification to “one embodiment” or “an embodiment” or “an example embodiment” means that a particular feature, structure, or characteristic described is included in at least one embodiment described herein and does not imply that the feature, structure, or characteristic is present in all embodiments described herein.

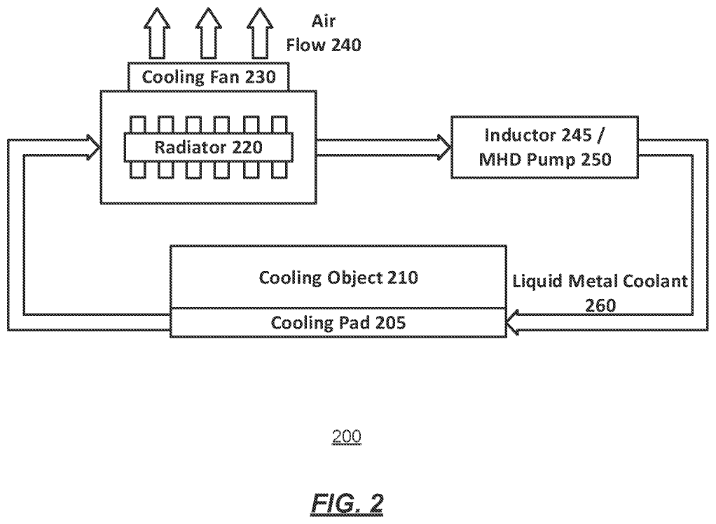

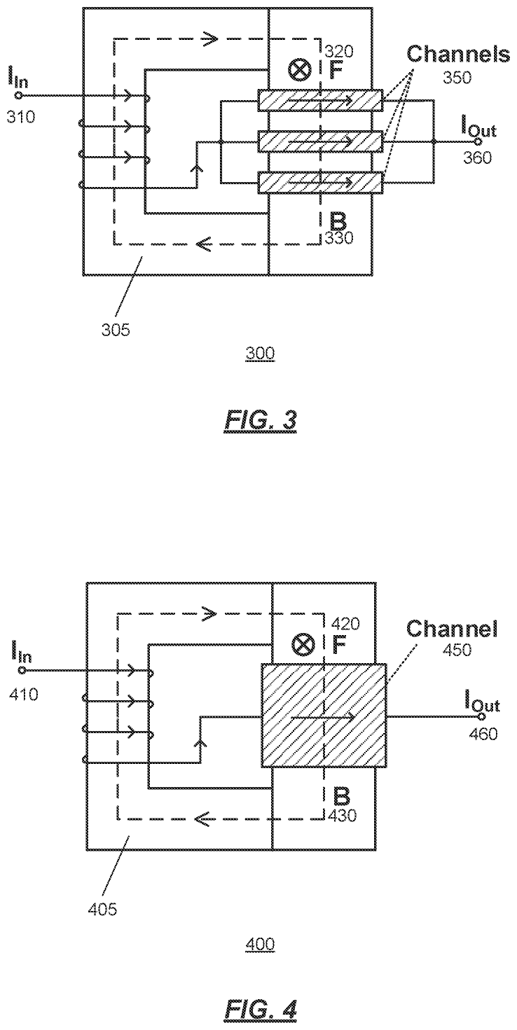

A liquid metal cooling system configuration is described. More particularly, an inductor with an integrated magnetohydrodynamics (MHD) pump, as described further herein, is applied in a liquid metal cooling system. FIG. 2 is a diagram of an implementation of a liquid metal cooling system 200. The system 200 comprises a cooling pad 205 with a cooling object 210 disposed thereon, a radiator 220, and an MHD pump 250. A cooling fan 230 provides air flow 240 from the radiator 220. An integrated inductor 245 comprises the MHD pump 250. A conductive liquid metal coolant 260 carries heat from the cooling pad 205 to the radiator 220.

MHD pump operation principles and structures are described. The MHD pump 250 utilizes the magnetic field produced by the integrated inductor 245. Liquid channels are clamped by magnetic cores, and the inductor current simultaneously flows through the conductive liquid metal coolant 260. A Lorentz force generated by the perpendicular magnetic field and current pushes the liquid metal in one direction. Flow rate is automatically adjusted by load condition, with the higher the power handled by inductor, the higher the flow rate. This feature eliminates the need for an auxiliary power supply to supply the current.

Implementations of structures of a pump system with inductor and integrated MHD pump are described with respect to FIGS. 3-8.

FIG. 3 shows a diagram of an implementation of a system 300 with multiple channels 350 with a C-shape magnetic core 305. Input current Iᵢₙ 310 is provided by the inductor with the integrated MHD pump. The liquid channels 350 are clamped by the core 305, and the inductor current simultaneously flows through the conductive liquid metal coolant 260. A Lorentz force F 320 generated by the perpendicular magnetic field B 330 and current pushes the liquid metal in one direction, with an output current Iₒᵤₜ 360 being provided Flow rate is automatically adjusted by load condition, with the higher the power handled by inductor, the higher the flow rate.

FIG. 4 shows a diagram of an implementation of a system 400 with a single channel with a C-shape magnetic core 405. Input current Iᵢₙ 410 is provided by the inductor with the integrated MHD pump. The liquid channel 450 is clamped by the core 405, and the inductor current simultaneously flows through the conductive liquid metal coolant 260. A Lorentz force F 420 generated by the perpendicular magnetic field B 430 and current pushes the liquid metal in one direction, with an output current Iₒᵤₜ 460 being provided. Flow rate is automatically adjusted by load condition, with the higher the power handled by inductor, the higher the flow rate.

FIG. 5 shows a diagram of an implementation of a system 500 with multiple channels with a rod magnetic core 505. Input current Iᵢₙ 510 is provided by the inductor with the integrated MHD pump. The liquid channels 550 are clamped by the core 505, and the inductor current simultaneously flows through the conductive liquid metal coolant 260. A Lorentz force F 520 generated by the perpendicular magnetic field B 530 and current pushes the liquid metal in one direction, with an output current Iₒᵤₜ 560 being provided. Flow rate is automatically adjusted by load condition, with the higher the power handled by inductor, the higher the flow rate.

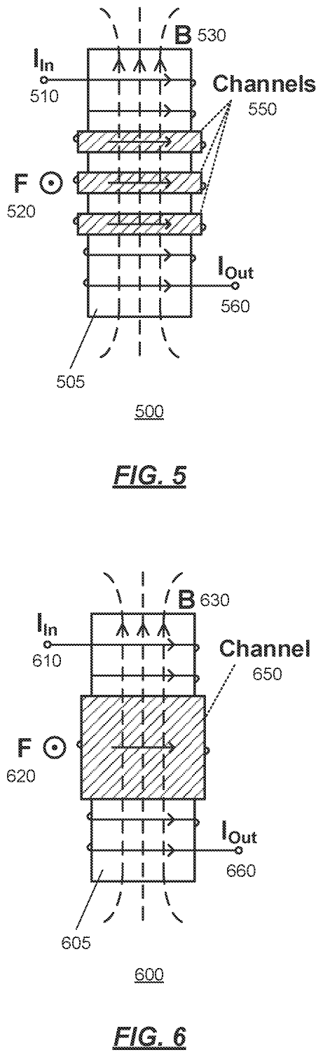

FIG. 6 shows a diagram of an implementation of a system 600 with a single channel with a rod magnetic core 605. Input current Iᵢₙ 610 is provided by the inductor with the integrated MHD pump. The liquid channel 650 is clamped by the core 605, and the inductor current simultaneously flows through the conductive liquid metal coolant 260. A Lorentz force F 620 generated by the perpendicular magnetic field B 630 and current pushes the liquid metal in one direction, with an output current Iₒᵤₜ 660 being provided. Flow rate is automatically adjusted by load condition, with the higher the power handled by inductor, the higher the flow rate.

FIG. 7 shows a diagram of an implementation of a system 700 with multiple channels with an EI magnetic core 705. Input current Iᵢₙ 710 is provided by the inductor with the integrated MHD pump. The liquid channels 750 are clamped by the core 705, and the inductor current simultaneously flows through the conductive liquid metal coolant 260. A Lorentz force F 720 generated by the perpendicular magnetic field B 730 and current pushes the liquid metal in one direction, with an output current Iₒᵤₜ 760 being provided. Flow rate is automatically adjusted by load condition, with the higher the power handled by inductor, the higher the flow rate.

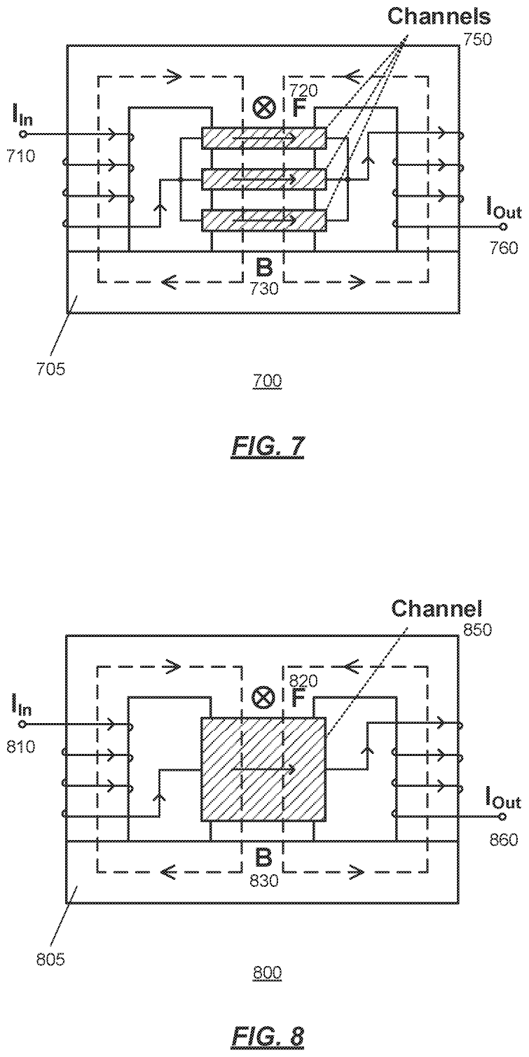

FIG. 8 shows a diagram of an implementation of a system 800 with a single channel with an EI magnetic core 805. Input current Iᵢₙ 810 is provided by the inductor with the integrated MHD pump. The liquid channel 850 is clamped by the core 805, and the inductor current simultaneously flows through the conductive liquid metal coolant 260. A Lorentz force F 820 generated by the perpendicular magnetic field B 830 and current pushes the liquid metal in one direction, with an output current Iₒᵤₜ 860 being provided. Flow rate is automatically adjusted by load condition, with the higher the power handled by inductor, the higher the flow rate.

Potential application topologies are described.

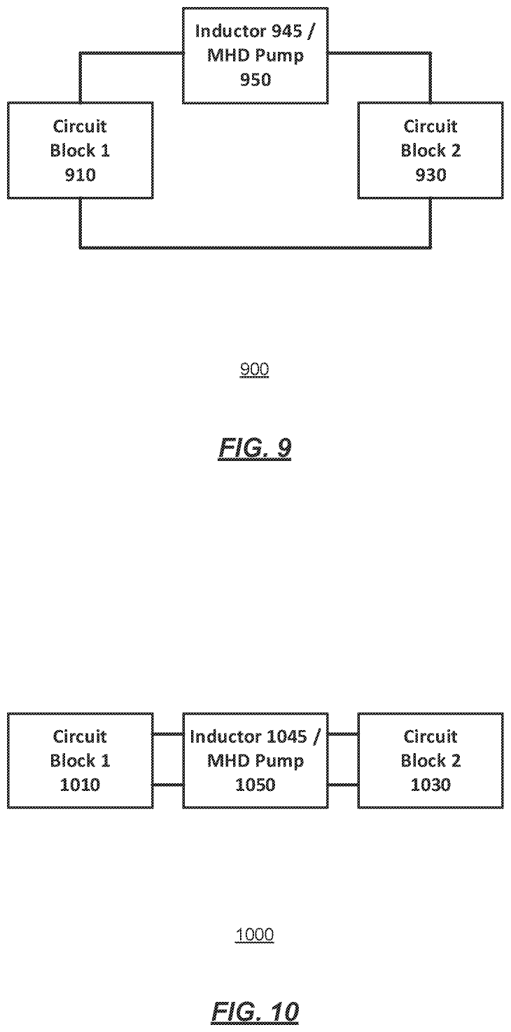

In electronics circuits, the inductor with built-in MHD pump (e.g., an inductor comprising an integrated MHD pump, such as the inductor 245 with the integrated MHD pump 250 in some implementations or those described with respect to FIGS. 3-8 in some implementations) is used to connect two blocks of circuits. The inductor can be placed in series with two circuit blocks, e.g., the inductor in the buck circuit. Also, the inductor can be placed in parallel with the two circuit blocks, e.g., the inductor in the buck/boost circuit. Diagrams for these two connection methods are shown in FIG. 9 and FIG. 10, respectively.

FIG. 9 shows an implementation of series connection topology 900. An inductor 945 with an integrated MHD pump 950 connects a first circuit block 1 910 with a second circuit block 2 930 in series.

FIG. 10 shows an implementation of parallel connection topology 1000. An inductor 1045 with an integrated MHD pump 1050 connects a first circuit block 1 1010 with a second circuit block 2 1030 in parallel.

Numerous characteristics and advantages provided by aspects of the present invention have been set forth in the foregoing description, together with details of structure and function. While the present invention is disclosed in several forms, it will be apparent to those skilled in the art that many modifications can be made therein without departing from the spirit and scope of the present invention and its equivalents. Therefore, other modifications or embodiments as may be suggested by the teachings herein are particularly reserved.

In an implementation, a system comprises: an inductor with a magnetic core structure and a gap in a core structure; and a magnetohydrodynamics (MHD) pump comprised within the inductor.

Implementations may include some or all of the following features. The MHD pump is integrated into the inductor. The system further comprises at least one channel with a C-shape magnetic core. The system further comprises at least one channel with a rod magnetic core. The system further comprises at least one channel with an EI magnetic core. The system further comprises at least one channel with a toroidal magnetic core. The inductor may have any types of magnetic core structure and a gap or gaps in the core structure.

In an implementation, a liquid metal cooling system comprises: an inductor comprising an integrated magnetohydrodynamics (MHD) pump; a cooling pad; a radiator; and a liquid metal coolant that carries heat from the cooling pad to the radiator.

Implementations may include some or all of the following features. The integrated MHD pump is configured to utilize the magnetic field produced by the inductor. The system further comprises a single liquid channel that is clamped by a magnetic core, and wherein the inductor current flows through the conductive liquid metal coolant. The system further comprises a plurality of liquid channels that are clamped by magnetic cores, and wherein the inductor current simultaneously flows through the conductive liquid metal coolant. A Lorentz force generated by a perpendicular magnetic field and a current pushes the liquid metal in one direction. A flow rate is automatically adjusted by load condition, wherein the higher the power handled by inductor, the higher the flow rate. The inductor comprising the integrated MHD pump is configured to connect two blocks of circuits. The inductor is placed in series with the two blocks of circuits. The inductor is placed in parallel with the two blocks of circuits. The system further comprises a core structure that provides a close-loop path for magnetic flux.

In an implementation, a system comprises: an inductor with a core structure that provide a close-loop path for magnetic flux; and an integrated magnetohydrodynamics (MHD) pump, wherein the inductor comprises the integrated MHD pump, wherein the inductor is configured to connect two blocks of circuits.

Implementations may include some or all of the following features. The inductor is placed in series with the two blocks of circuits. The inductor is placed in a buck circuit or in a buck/boost circuit. The inductor is placed in parallel with the two blocks of circuits.

As used herein, the singular form “a,” “an,” and “the” include plural references unless the context clearly dictates otherwise.

As used herein, the terms “can,” “may,” “optionally,” “can optionally,” and “may optionally” are used interchangeably and are meant to include cases in which the condition occurs as well as cases in which the condition does not occur.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed:

1. A system comprising:
an inductor with a magnetic core structure and a gap in a core structure; and
a magnetohydrodynamics (MHD) pump comprised within the inductor.

2. The system of claim 1, wherein the MHD pump is integrated into the inductor.

3. The system of claim 1, further comprising at least one channel with a C-shape magnetic core.

4. The system of claim 1, further comprising at least one channel with a rod magnetic core.

5. The system of claim 1, further comprising at least one channel with an EI magnetic core.

6. The system of claim 1, further comprising at least one channel with a toroidal magnetic core.

7. A liquid metal cooling system comprising:
an inductor comprising an integrated magnetohydrodynamics (MHD) pump;
a cooling pad;
a radiator; and
a liquid metal coolant that carries heat from the cooling pad to the radiator.

8. The system of claim 7, wherein the integrated MHD pump is configured to utilize the magnetic field produced by the inductor.

9. The system of claim 7, further comprising a single liquid channel that is clamped by a magnetic core, and wherein the inductor current flows through the conductive liquid metal coolant.

10. The system of claim 7, further comprising a plurality of liquid channels that are clamped by magnetic cores, and wherein the inductor current simultaneously flows through the conductive liquid metal coolant.

11. The system of claim 10, wherein a Lorentz force generated by a perpendicular magnetic field and a current pushes the liquid metal coolant in one direction.

12. The system of claim 11, wherein a flow rate is automatically adjusted by load condition, wherein the higher the power handled by inductor, the higher the flow rate.

13. The system of claim 7, wherein the inductor comprising the integrated MHD pump is configured to connect two blocks of circuits.

14. The system of claim 13, wherein the inductor is placed in series with the two blocks of circuits.

15. The system of claim 13, wherein the inductor is placed in parallel with the two blocks of circuits.

16. The system of claim 7, further comprising a core structure that provides a close-loop path for magnetic flux.

17. A system comprising:
an inductor with a core structure that provide a close-loop path for magnetic flux; and
an integrated magnetohydrodynamics (MHD) pump, wherein the inductor comprises the integrated MHD pump, wherein the inductor is configured to connect two blocks of circuits.

18. The system of claim 17, wherein the inductor is placed in series with the two blocks of circuits.

19. The system of claim 17, wherein the inductor is placed in a buck circuit or in a buck/boost circuit.

20. The system of claim 17, wherein the inductor is placed in parallel with the two blocks of circuits.
